(19) United States
(12) Patent Application Publication
(10) Pub. No.: US 2007/0051963 A1
(43) Pub. Date: Mar. 8, 2007

(54) Semiconductor light source

(76) Inventor: Yifan Chen, Chatham, NJ (US)

Correspondence Address: Lucent Technologies Inc.;Docket Administrator - Room 3J-219, 101 Crawfords Corner Road, Holmdel, NJ, 07733-3030, US

(21) Appl. No.: 11/219,924

(22) Filed: Sep. 6, 2005

(51) Int. Cl. H01L 33/00; H01L 21/00

(52) U.S. Cl. 257/96; 257/103; 438/46; 257/E33.037

(57) ABSTRACT

A light source is based on a combination of silicon and calcium fluoride (CaF₂). The silicon and the calcium fluoride need not be pure, but may be doped, or even alloyed, to control their electrical and/or physical properties. Preferably, the light source employs interleaved portions, e.g., arranged as a multilayer structure, of silicon and calcium fluoride and operates using intersubband transitions in the conduction band so as to emit light in the near infrared spectral range. The light source may be arranged so as to form a quantum cascade laser, a ring resonator laser, a waveguide optical amplifier.

### TECHNICAL FIELD

This invention relates to semiconductor light sources, and in particular to semiconductor lasers.

### BACKGROUND OF THE INVENTION

Ordinary semiconductor light sources and semiconductor lasers employ direct bandgap compound semiconductors such as Gallium Arsenide (GaAs). Typically, they work on the principle of interband electron transition, where light is emitted when an excited electron in the semiconductor material transits from the conduction band edge to the valence band edge.

By contrast, indirect bandgap semiconductors, such as Silicon (Si), require a phonon to be emitted or absorbed in order for an electron to transit from the conduction band edge to the valence band edge. This requirement makes the probability of such a transition less likely than when a phonon is not required, under otherwise the same circumstances. As a result, the emission of light is also less likely, and hence, Si, although the most widely used semiconductor, is not regarded as a suitable material for the fabrication of a semiconductor light source.

Another type of semiconductor light source, the semiconductor quantum cascade laser, employs intraband transitions, also known as inter-subband transitions, in which electrons excited to a higher level energy band, i.e., a higher energy subband, in the conduction or the valence band fall to a lower level energy band, i.e., a lower energy subband, in the same band. Quantum cascade lasers are conventionally based on compound semiconductors such as gallium indium arsenide and aluminum indium arsenide (GaInAs/AlInAs). GaInAs/AlInAs quantum cascade lasers typically produce light in the mid-infrared (IR) spectral range, e.g., between 4 and 13 μm.

Quantum cascade lasers have also been researched using a combination of silicon and germanium. Unfortunately, there is considerable difficulty in achieving a laser based on Si/Ge. This is because of a) the large lattice mismatch, e.g., 4%, between Si and Ge, b) the fact that the valence band must be used, which is less desirable due to additional complexities than using the conduction band, and c) the small band offset between the conduction and valence bands of the Si and the Ge. Although some electroluminescence has been observed, it is not believed that lasing has been achieved using Si and Ge. Furthermore, it is expected that even if lasing were to be achieved using Si and Ge that the operating wavelength would be greater that 18 μm, which would not be useful for current telecommunications applications.

### SUMMARY OF THE INVENTION

The problem of developing a semiconductor light source that can be constructed on a silicon-based substrate is overcome, in accordance with principles of the invention, by a light source that is based on a combination of silicon and calcium fluoride (CaF₂). The silicon and the calcium fluoride need not be pure, but may be doped, or even alloyed, to control their electrical and/or physical properties.

Preferably, the light source employs interleaved portions, e.g., arranged as a multilayer structure, of silicon and calcium fluoride and operates using intersubband transitions in the conduction band. More specifically, the Si, which has a smaller bandgap than the CaF₂ provides the quantum well while the CaF₂, which has a larger bandgap than the Si, provides the barrier. Advantageously, such a light source has a low lattice mismatch, e.g., as small as 0.55%, and a large conduction band offset, e.g., approximately 2.2 electron volts. A Si and CaF₂ light source may be tuned to emit light in the near infrared spectral range, e.g., between 1 μm and 4 μm, and more specifically, at 1.5 μm and 1.3 μm, each of which is suitable for modern telecommunications applications. Further advantageously, a light source based primarily on silicon is cheaper to manufacture than a light source based on GaAs and it is easier to integrate such a light source with conventional electronics based on silicon technology.

Combining, e.g., doping and/or alloying the Si and CaF₂ with other material, such as germanium and cadmium fluoride (CdF₂), provides for the possibility of further customization of the light source's properties. For example, perfect lattice matching may be achieved by alloying a small amount of Ge with the silicon. By alloying cadmium fluoride (CdF₂) with the CaF₂ and doping it with trivalent metal ions such as gallium (Ga), the resulting combination may be made conductive.

The light source may be arranged so as to form a quantum cascade laser, a ring resonator laser, a waveguide optical amplifier.

### BRIEF DESCRIPTION OF THE DRAWING

In the drawing:

FIG. 1 shows an exemplary semiconductor light source constructed based on a combination of silicon (Si) and calcium fluoride (CaF₂) in accordance with principles of the invention;

FIG. 2 schematically depicts the basic portion of the conduction band diagram of the exemplary semiconductor light source shown in FIG. 1 when no voltage is applied;

FIG. 3 schematically depicts an extended portion of the conduction band diagram of the exemplary semiconductor light source shown in FIG. 1 when a potential difference is applied;

FIG. 4 shows a graph showing an approximation of the general relationship between quantum well width in angstroms and the corresponding subband energies that result, expressed in electron volts (eV);

FIG. 5 shows an active region of another exemplary semiconductor light source that is suitable for use in various laser configurations;

FIG. 6 schematically depicts the conduction band diagram of exemplary semiconductor light source active region shown in FIG. 5 when a voltage is applied across it;

FIG. 7 shows a “superlattice” region which is employed to function as an energy relaxation region and as an injection region;

FIG. 8 schematically depicts the conduction band diagram of the exemplary superlattice of FIG. 7 when no voltage is applied across it;

FIG. 9 schematically depicts the conduction band diagram of the exemplary superlattice of FIG. 7 when a voltage is applied across it;

FIG. 10 shows a portion of the cross sectional structure of an exemplary quantum cascade laser which employs multiple repetitions of the layers that form the active region of FIG. 5 and the layers that form superlattice region of FIG. 7; and

FIG. 11 shows a portion of a three dimensional view of the exemplary quantum cascade laser shown in FIG. 10.

### DETAILED DESCRIPTION

The following merely illustrates the principles of the invention. It will thus be appreciated that those skilled in the art will be able to devise various arrangements that, although not explicitly described or shown herein, embody the principles of the invention and are included within its spirit and scope. Furthermore, all examples and conditional language recited herein are principally intended expressly to be only for pedagogical purposes to aid the reader in understanding the principles of the invention and the concepts contributed by the inventor(s) to furthering the art, and are to be construed as being without limitation to such specifically recited examples and conditions. Moreover, all statements herein reciting principles, aspects, and embodiments of the invention, as well as specific examples thereof, are intended to encompass both structural and functional equivalents thereof. Additionally, it is intended that such equivalents include both currently known equivalents as well as equivalents developed in the future, i.e., any elements developed that perform the same function, regardless of structure.

In the claims hereof any element expressed as a means for performing a specified function is intended to encompass any way of performing that function. This may include, for example, a) a combination of electrical or mechanical elements which performs that function or b) software in any form, including, therefore, firmware, microcode or the like, combined with appropriate circuitry for executing that software to perform the function, as well as mechanical elements coupled to software controlled circuitry, if any. The invention as defined by such claims resides in the fact that the functionalities provided by the various recited means are combined and brought together in the manner which the claims call for. Applicant thus regards any means which can provide those functionalities as equivalent as those shown herein.

Software modules, or simply modules which are implied to be software, may be represented herein as any combination of flowchart elements or other elements indicating performance of process steps and/or textual description. Such modules may be executed by hardware that is expressly or implicitly shown.

Unless otherwise explicitly specified herein, the drawings are not drawn to scale.

Additionally, unless otherwise explicitly specified herein, any lens shown and/or described herein is actually an optical system having the particular specified properties of that lens. Such an optical system may be implemented by a single lens element but is not necessarily limited thereto. Similarly, where a mirror is shown and/or described what is actually being shown and/or described is an optical system with the specified properties of such a mirror, which may be implemented by a single mirror element but is not necessarily limited to a single mirror element. This is because, as is well known in the art, various optical systems may provide the same functionality of a single lens element or mirror but in a superior way, e.g., with less distortion. Furthermore, as is well known in the art, the functionality of a curved mirror may be realized via a combination of lenses and mirrors and vice versa. Moreover, any arrangement of optical components that are performing a specified function, e.g., an imaging system, gratings, coated elements, and prisms, may be replaced by any other arrangement of optical components that perform the same specified function. Thus, unless otherwise explicitly specified here, all optical elements or systems that are capable of providing specific function within an overall embodiment disclosed herein are equivalent to one another for purposes of the present disclosure.

In the description, identically numbered components within different ones of the FIGs. refer to the same components.

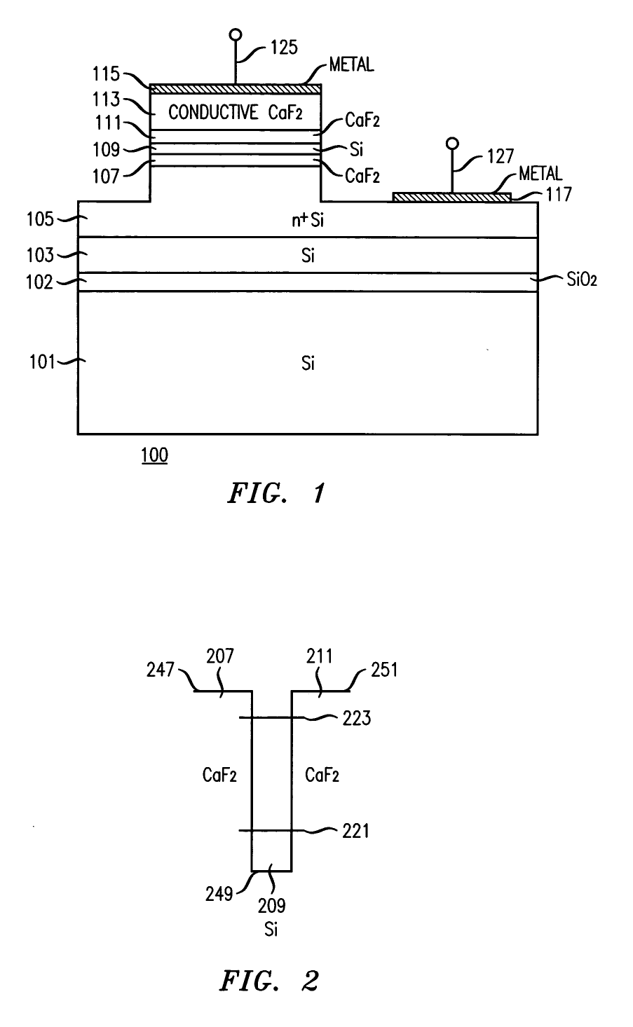

FIG. 1 shows an exemplary semiconductor light source 100 constructed on a silicon-based substrate, in accordance with principles of the invention. More specifically, light source 100 is based on a combination of silicon (Si) and calcium fluoride (CaF₂). The silicon and the calcium fluoride may be doped or alloyed to control their electrical and/or physical properties.

Semiconductor light source 100 works as a basic light emitting unit. On a theoretical level, semiconductor light source 100 is a single quantum well structure and in particular, it is a single silicon quantum well that has a CaF₂ barrier. More specifically, since Si has a smaller bandgap than CaF₂, the Si provides the quantum well, while the CaF₂, which has a larger bandgap than the Si, provides the barrier. An electrode on one side of the quantum well structure supplies electrons that tunnel through the barrier and may be carried off by an electrode on the other side of the quantum well structure. Preferably, semiconductor light source 100 operates using intersubband transitions in the conduction band. Advantageously, such a light source has a low lattice mismatch, e.g., as small as 0.55%, and a large conduction band offset, e.g., approximately 2.2 electron volts.

Physically, light source 100 includes a) silicon (Si) substrate 101, b) silicon dioxide layer SiO₂ 102, c) Si layer 103, d) conductive Si (n⁺ Si) layer 105, e) CaF₂ layer 107, f) Si layer 109, g) CaF₂ layer 111, h) conductive CaF₂ layer 113 i) metal layers 115 and 117, and j) conductors 125 and 127.

Substrate 101 may be a conventional silicon wafer, such as those commercially available. Silicon dioxide layer 102 is a conventional layer of SiO₂, commonly referred to as a buried oxide (BOX) layer. SiO₂ layer 102 has a lower index of refraction than Si. Thus, this layer functions to provide confinement of light generated above in regions that have a higher index of refraction from leaking out of that region. In other words, SiO₂ layer 102 provides optical isolation that keeps generated light from leaking into substrate 101. Si layer 103 is a single crystalline layer of Si that provides a suitable base on which to grow additional single crystalline layers that make up the active layers of light source 100. Wafers made up of Si substrate 101, silicon dioxide layer 102, and Si layer 103 are available commercially and are know as silicon on insulator (SOI) wafers.

Conductive silicon layer 105 may be doped to be n-type, so that it is suitably conductive and can function effectively as one of the electrodes of the quantum well structure. In other words, conductive silicon layer 105 is arranged to act as a plate electrode. Those of ordinary skill in the art would readily be able to appropriately dope conductive silicon layer 105 to achieve a desired level of conductivity. Typically, the more conductive silicon layer 105 is, the more light will be generated. Conductive silicon layer 105 is electrically connected to metal electrode layer 117, which is in turn coupled to conductor 127, so that electricity is conducted to silicon layer 105 via conductor 127 and electrode layer 117.

CaF₂ layer 107 is a thin layer, e.g., 5 to 50 angstroms, of CaF₂ that does not need to be doped. Si layer 109 is a thin layer, e.g., 5 to 100 angstroms, of Si that does not need to be doped. CaF₂ layer 111 is a thin layer, e.g., typically 5 to 50 angstroms, of CaF₂ that does not need to be doped.

Conductive CaF₂ layer 113 is layer of CaF₂ that is combined with at least one other material. Typically, conductive CaF₂ layer 113 is thicker than thinner CaF₂ layers 107 and 111. Conductive CaF₂ layer 113 is combined, e.g., doped or alloyed, with the at least one other material so that the resulting combination is effectively conductive, e.g., n-type conductive. One way to achieve n-type conductivity is to alloy CdF₂ with the CaF₂ of layer 113 and then doping the entire alloy with a trivalent metal ion, e.g., gallium (Ga). Note that by an alloy what is meant is a greater concentration of CdF₂ than would be considered to be a mere dopant. For example, the doping of conductive Si layer 105 may be performed using a concentration of 0.005% of antimony with the silicon while the alloying of CaF₂ with CdF₂ may consist of 1% of CdF₂ within the CaF₂.

Conductive CaF₂ layer 113 acts as an electrode, similar to conductive silicon layer 105. Conductive CaF₂ layer 113 is electrically connected to metal electrode layer 115, which is in turn coupled to conductor 125, so that electricity is brought to conductive CaF₂ layer 113 via conductor 125 and electrode layer 115.

A Si and CaF₂ light source, such as exemplary semiconductor light source 100 of FIG. 1, may be tuned to emit light in the near infrared spectral range, e.g., between 1 μm and 4 μm, and more specifically, at 1.3 or 1.5 μm, each of which is suitable for modern telecommunications applications. Further advantageously, a light source based primarily on silicon is cheaper to manufacture than a light source based on other compound semiconductors. It is also easier to integrate a silicon-based light source with conventional electronics and photonics that are based on silicon technology.

Note that although n-type Si and CaF₂ have been shown, those of ordinary skill in the art will recognize that it may be possible to similarly employ p-type Si and CaF₂.

FIG. 2 schematically depicts the basic portion of the conduction band diagram of an exemplary semiconductor light source such as exemplary semiconductor light source 100 (FIG. 1) when no voltage is applied between conductor 125 and 127. Region 209 (FIG. 2) depicts the Si quantum well which is formed by CaF₂ regions 207 and 211. Note that region 209 corresponds to Si layer 109 (FIG. 1) while CaF₂ regions 207 and 211 (FIG. 2) correspond to CaF₂ layers 107 and 111 (FIG. 1) respectively. Also note that line segments 247, 249, and 251 defining regions 207, 209, and 211 represent the bottom of the conduction band for the material of their associated layers. The conduction band offset, which is the difference in potential between the bottom of the conduction band in region 207 or region 211 and the bottom of the conduction band in region 209, which corresponds to the height of the quantum well, is approximately 2.2 electron volts.

Also shown in FIG. 2 are energy bands 221 and 223, having energies E1 and E2, where E2 is greater than E1. While electrons are within region 209 they can only exist at one of energy bands 221 and 223. The difference in energy between E2 and E1 depends on the particular materials employed and the thicknesses of their respective layers. Preferably the energy difference between E2 and E1 may be on the order of 0.8 eV, which corresponds to a light wavelength on the order of 1.5 μm. Alternatively, the energy difference between E2 and E1 may be on the order of 0.95 eV, which corresponds to a light wavelength on the order of 1.3 μm.

Combining, e.g., doping and/or alloying the Si and CaF₂ with other material, such as germanium and cadmium fluoride (CdF₂) provides for the possibility of further customization of the properties of a semiconductor light source arranged in accordance with the principles of the invention. For example, in exemplary semiconductor light source 100 (FIG. 1) perfect lattice matching may be achieved by alloying a small amount of Ge with the silicon of silicon layer 109. By alloying cadmium fluoride (CdF₂) with the CaF₂ of one, or both, of CaF₂ layers 107 or 111, the resulting combination may be made conductive. Adding such materials changes the bandgap of the material to which the adding is done, and changes its band alignment as well. As a result, when such materials are using in combination to form exemplary light structure 100, the gap between the resulting subbands changes as compared to when no material is added. As a result, one can control the gap in the subbands, and hence control the wavelength of the light that is produced. As will be readily understood by those of ordinary skill in the art, the actual conduction band diagram for such embodiments of the invention will be similar to, but not necessarily exactly the same as, the conduction band diagram of FIG. 2.

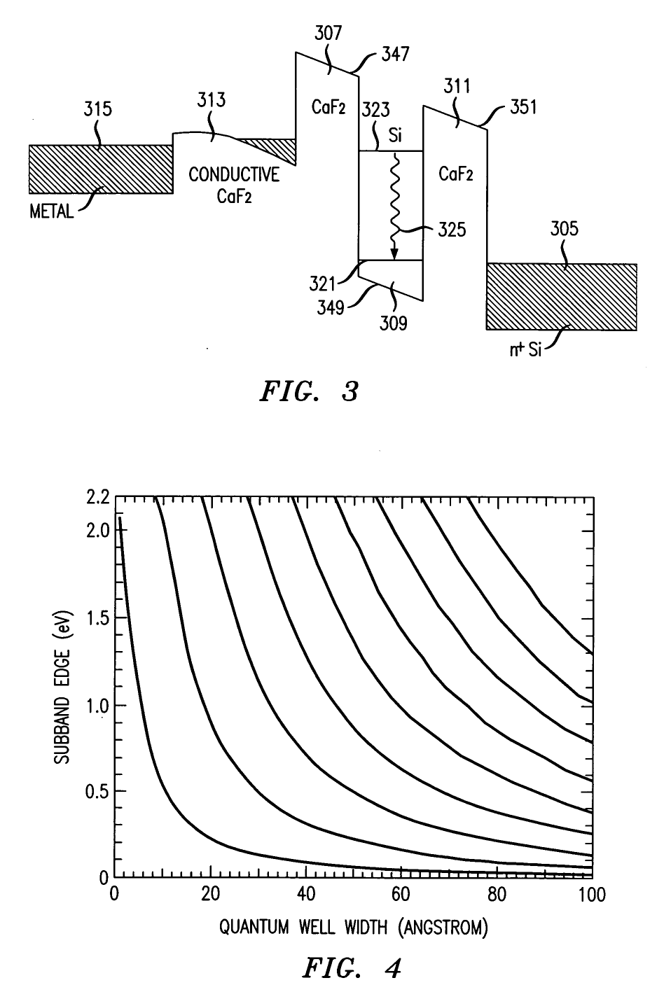

Similar to FIG. 2, FIG. 3 schematically depicts an extended portion of the conduction band diagram of an exemplary semiconductor light source arranged in accordance with the principles of the invention, such as exemplary semiconductor light source 100 (FIG. 1). However, unlike FIG. 2, in FIG. 3 the conduction band diagram is for a time when there is a potential difference between conductor 125 and conductor 127, as there is under typical operating conditions. Region 309 (FIG. 3) depicts the Si quantum well which is formed by CaF₂ regions 307 and 311. Note that region 309 corresponds to Si layer 109 (FIG. 1) while CaF₂ regions 307 and 311 (FIG. 3) correspond to CaF₂ layers 107 (FIG. 1) and 111 respectively. Note that, as compared with bottom 249 (FIG. 2) of corresponding region 209, bottom 349 (FIG. 3) of region 309 (FIG. 3) is tilted. This is due to the application of the voltage. Similarly, top segments 347 and 351 of regions 307 and 311, respectively, which correspond to the bottom of the conduction band, are tilted, as compared to respective corresponding segments 247 (FIG. 2) and 251. However, the conduction band offset, which is the difference in potential between the bottom of the conduction band in region 307 or the bottom of the conduction band in region 311, and the bottom of the conduction band in region 309 that is most closely adjacent thereto, is the same as when no voltage is applied, as shown in FIG. 2, and so it is still approximately 2.2 electron volts.

Also shown in FIG. 3 are energy bands 321 and 323, having energies E1 and E2, where E2 is greater than E1. While electrons are within region 309 they can only exist at one of energy bands 321 and 323. The difference in energy between E2 and E1 depends on the particular materials employed and the thicknesses of their respective layers. Preferably the energy difference between E2 and E1 may be on the order of 0.8 eV, which corresponds to a light wavelength on the order of 1.5 μm. Alternatively, the energy difference between E2 and E1 may be on the order of 0.95 eV, which corresponds to a light wavelength on the order of 1.3 μm.

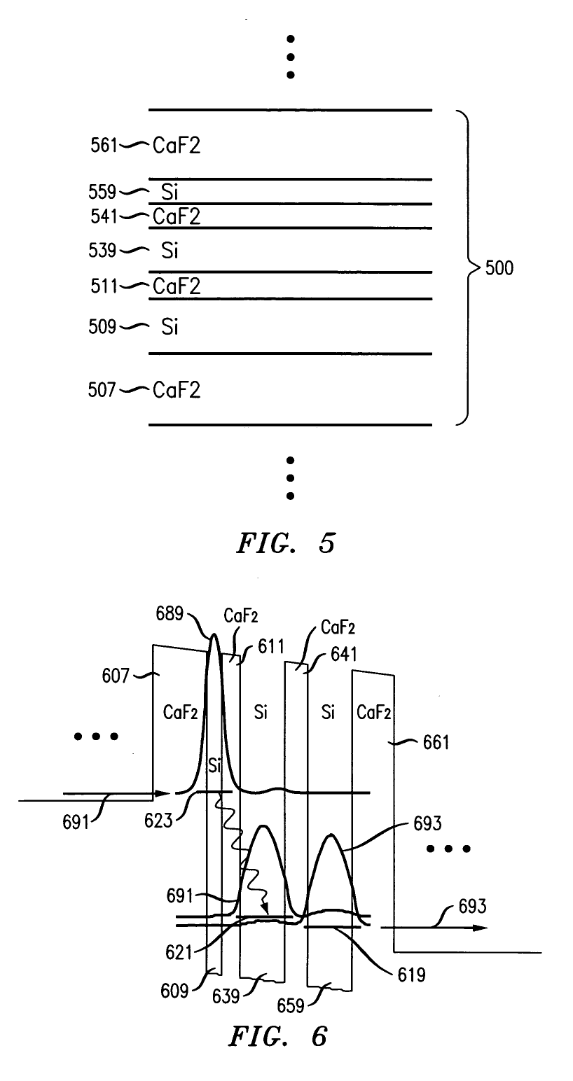

For example, FIG. 4 shows a graph showing an approximation of the general relationship between quantum well width in angstroms and the corresponding subband energies that result, expressed in electron volts (eV). Quantum well width corresponds to the thickness of Si layer 109. Note that it is desirable to have at least two subbands in the quantum well and for the energy between those two subbands to correspond to the desired wavelength of light. For example, with two subbands spaced apart by approximately 0.8 eV the resulting light will be approximately 1.5 μm and with two subbands spaced apart by approximately 0.95 eV the resulting light will be approximately 1.3 μm. As explained hereinabove, adding materials to the basic layer material can be employed to change the gap between the subbands, and hence the wavelength of the light produced. Those of ordinary skill in the art will be readily able to select appropriate widths and additive materials to generate desired wavelengths of light.

Returning to FIG. 3, note that conduction regions 315 and 305, corresponding to the conduction bands of metal layer 115 (FIG. 1) and conductive silicon layer 105, respectively, are filled with electrons. Also, the bottom of conduction band for region 313 is filled with electrons. Note that electrons supplied from conductive region 315 pass through conductive CaF₂ region 313, which corresponds to conductive CaF₂ layer 113 (FIG. 1). These electrons then quantum mechanically tunnel through CaF₂ region 307 to reach energy level 323 in the quantum well corresponding to region 309. When the electron spontaneously transits from energy level 323 to energy level 321 it emits a photon, as represented schematically by the quantum transition 325. The reduced energy electron then tunnels through CaF₂ region 311 to reach conductive silicon region 305. From there the electron may exit the structure.

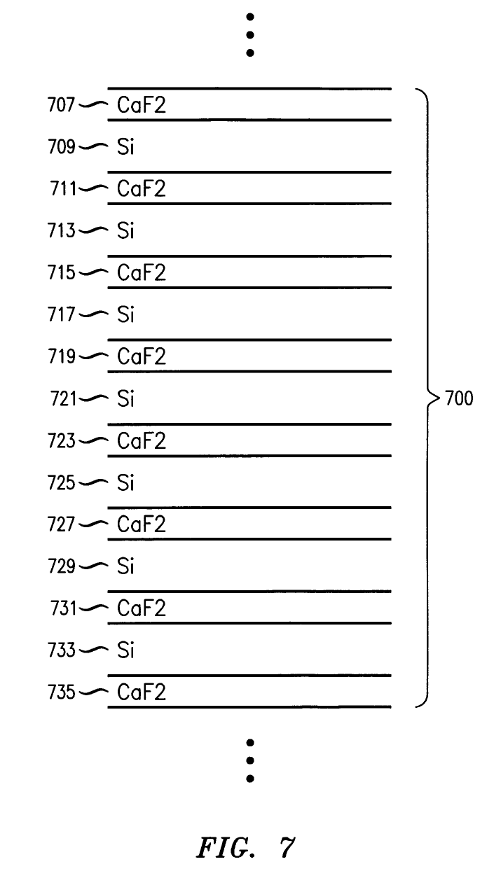

FIG. 5 shows active region 500 of another exemplary semiconductor light source. Active region 500 is suitable for use in various laser configurations. Active region 500 includes CaF₂ layers 507, 511, 541, and 561 as well as Si layers 509, 539 and 561. Note that the relative thickness of the layers are not to scale but are represented for pedagogical purposes. Note that the basic material of each of the layers may be combined with other materials as described herein above for layers of Si and CaF₂, so as to control the resulting band gaps. Also note that the concentrations of any dopant or alloying material in any doped or alloyed layer, respectively, may be independent of the concentration of dopant or alloying material in any other layer.

FIG. 6 schematically depicts the conduction band diagram of exemplary semiconductor light source active region 500 (FIG. 5) when a voltage is applied across it. Overlayed on the conduction band diagram of FIG. 6 is the probability density that an electron will be found in any available subband within the quantum wells. Note that such probability density is calculated for modulus square of the wavefunction associated with the energy state.

More specifically, region 609 depicts a Si quantum well between CaF₂ regions 607 and 611, each of which acts as a barrier. The quantum well is formed by Si layer 509 (FIG. 5) being located between CaF₂ layers 507 and 511, in that region 609 (FIG. 6) corresponds to Si layer 509 (FIG. 5) and regions 607 (FIG. 6) and 611 correspond to CaF₂ layers 507 (FIG. 5) and 511, respectively. Similarly, region 639 (FIG. 6) depicts the Si quantum well which is formed by CaF₂ regions 611 and 641 acting as barrier. Note that region 639 corresponds to Si layer 539 (FIG. 5) while CaF₂ regions 611 (FIG. 6) and 641 correspond to CaF₂ layers 511 (FIG. 5) and 541 respectively. Likewise, region 659 (FIG. 6) depicts the Si quantum well which is formed by Si layer 559 (FIG. 5) with CaF₂ regions 647 (FIG. 6) and 661, corresponding to layers 557 (FIG. 5) and 561 acting as barrier. When there is no doping, the conduction band offset, which is the difference in potential between the bottom of the conduction band in one of CaF₂ regions 607 (FIG. 6), 611, 641, and 661 and the bottom of the conduction band in its adjacent one of Si regions 609, 639, or 659, are the same.

Due to the multiple layer structure and the widths of the layers of exemplary semiconductor light source active region 500 (FIG. 5), quantum wells 609 (FIG. 6), 639, and 659 formed thereby interact so as to form a quantum well system. In the quantum well system there are energy bands 619, 621 and 623, having energies E1, E2, and E3, where E3 is greater than E2 and E2 is greater than E1. Electrons that are within exemplary semiconductor light source active region 500 (FIG. 5) can only exist at one of energy bands 621 (FIG. 6), 623 and 619. Although each of these levels is shown as existing in only one of the quantum wells, there is a probability, indicated, by the probability density, that an electron will be found at that energy level but in a different quantum well. Nevertheless, for clarity, each energy level is shown in the respective quantum well that has the largest probability of an electron being found in that quantum well at that energy level.

The difference in energy between the energy levels depends on the particular materials employed and the thicknesses of the layers of the employed materials. Preferably the energy difference between E2 and E1 is on the order of 0.8 eV, which corresponds to a light wavelength on the order of 1.5 μm. Alternatively, the energy difference between E2 and E1 is on the order of 0.95 eV, which corresponds to a light wavelength on the order of 1.3 μm. Also, preferably, the energy difference between E2 and E3 is on the order of the energy of a phonon.

The primary operation is for an electron to tunnel through CaF₂ region 607 to reach energy level E1 in quantum well 609. A photon is emitted as the electron tunnels through CaF₂ region 611 to quantum well 639 while droping to energy level E2 therein. Thereafter, a phonon is emitted as the electron tunnels through CaF₂ region 641 while dropping to energy level E3 in quantum well 659. This emission of a phonon and dropping from E2 to E3 is conventionally called relaxation. The electron then exits active region 500 by tunneling through CaF₂ region 661.

FIG. 7 shows so-called “superlattice” region 700 which is employed to function as an energy relaxation region and as an injection region. Functionally, superlattice region 700 efficiently transports electrons from one active region to the other. More particularly, superlattice region 700 needs to be of sufficient length so that the bias across it and the two active regions it connects is such that the lowest energy level, e.g., tile relaxation energy level, of the higher potential level one of the two active regions matches the highest energy level of the lower potential level one of the two active regions coupled by superlattice region 700.

Superlattice region 700 is made up of alternating layers of Si, e.g., Si layers 709, 713, 717, 721, 725, 729, and 733, and CaF₂, e.g., CaF₂, layers 707, 711, 715, 719, 723, 727, 731 and 735. Typically the Si layers of superlattice region 700 are lightly doped to improve conductivity and facilitate electron transport through superlattice region 700. The CaF₂ layers of superlattice region 700 may be doped. Typically the widths of the CaF₂ layers may remain constant while the widths of the Si layers are varied. The number of layers employed and the doping required, if any, for each of the layers needs to be such that the resulting energy levels of the superlattice overlap when a potential voltage is applied so as a) to form a so called “mini” band and b) to provide enough spatial separation so that the applied potential difference can shift the highest energy band of the active region which is being supplied with electrons from superlattice region 700 to the same energy level as the relaxation energy level from which superlattice region 700 is receiving electrons. Thus, the particular design in terms of number of layers and their widths is dependent on the particular operating potential difference desired and the energy levels of the active regions when operating, and should be such that under typical operating conditions the mini band is formed. Those of ordinary skill in the art will readily be able to design superlattice regions for various applications.

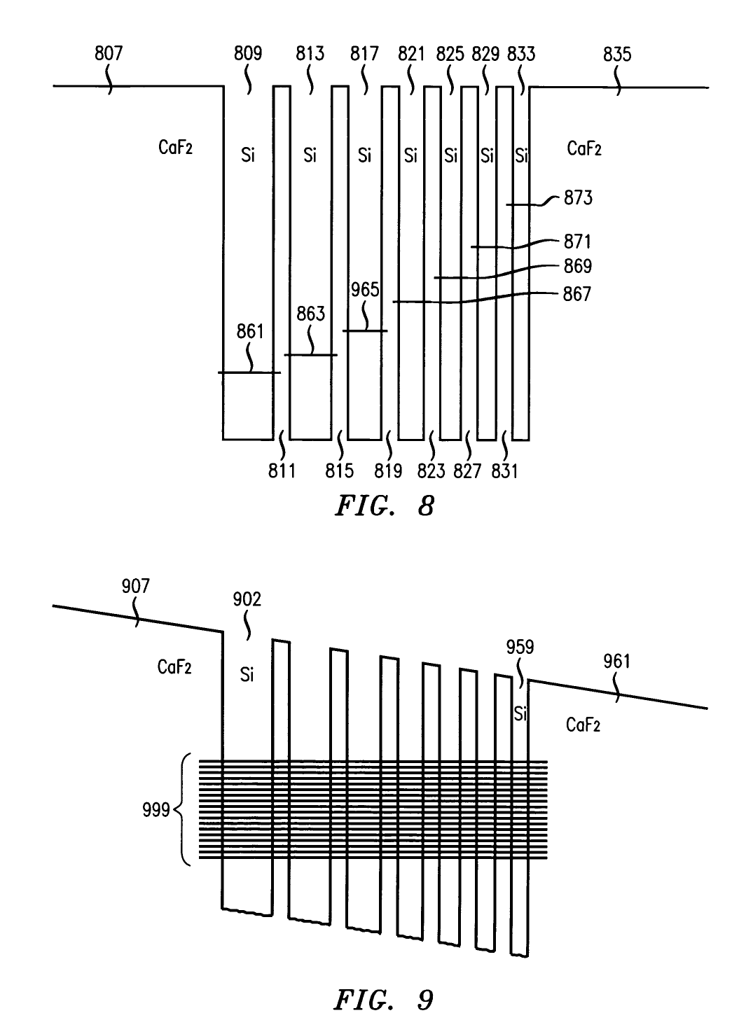

FIG. 8 schematically depicts the conduction band diagram of exemplary superlattice 700 (FIG. 7) when no voltage is applied across it. As shown, each quantum well 809 (FIG. 8), 813, 817, 821, 825, 829, and 833, formed by an Si layer of superlattice region 700 (FIG. 7) sandwiched between two of CaF₂ barriers 807 (FIG. 8), 811, 815, 819, 823, 827, 831 and 835, which corresponds to the CaF₂ layers of superlattice region 700 (FIG. 7) has a preferred respective one of energy states 861, 863, 865, 867, 869, 871, and 873.

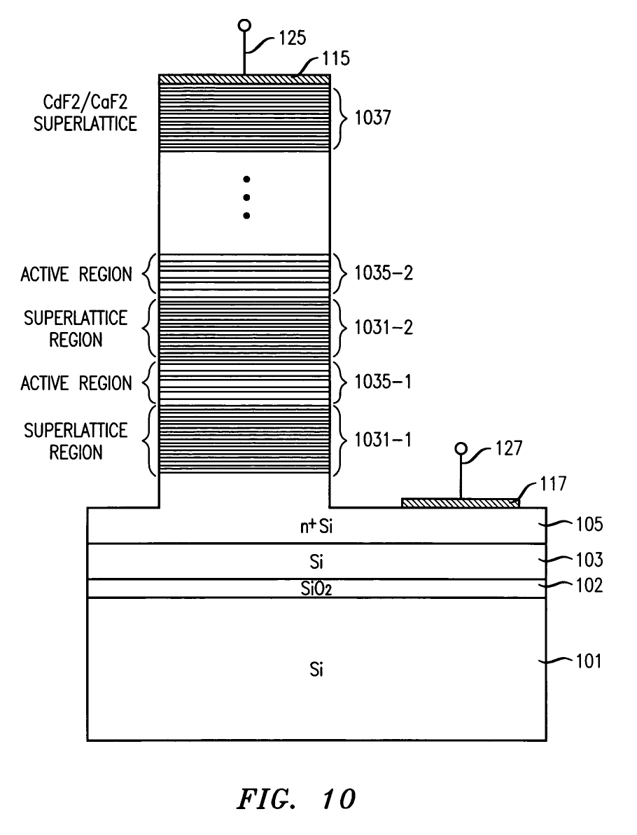

FIG. 9 schematically depicts the conduction band diagram of exemplary superlattice 700 (FIG. 7) when a voltage is applied across it, e.g., under typical operating conditions. As shown in FIG. 9, mini band 999 is formed through which electrons can easily pass. Also, the bottom of the conduction band for each successive layer has shift from its value when no potential difference is applied, as in FIG. 8.

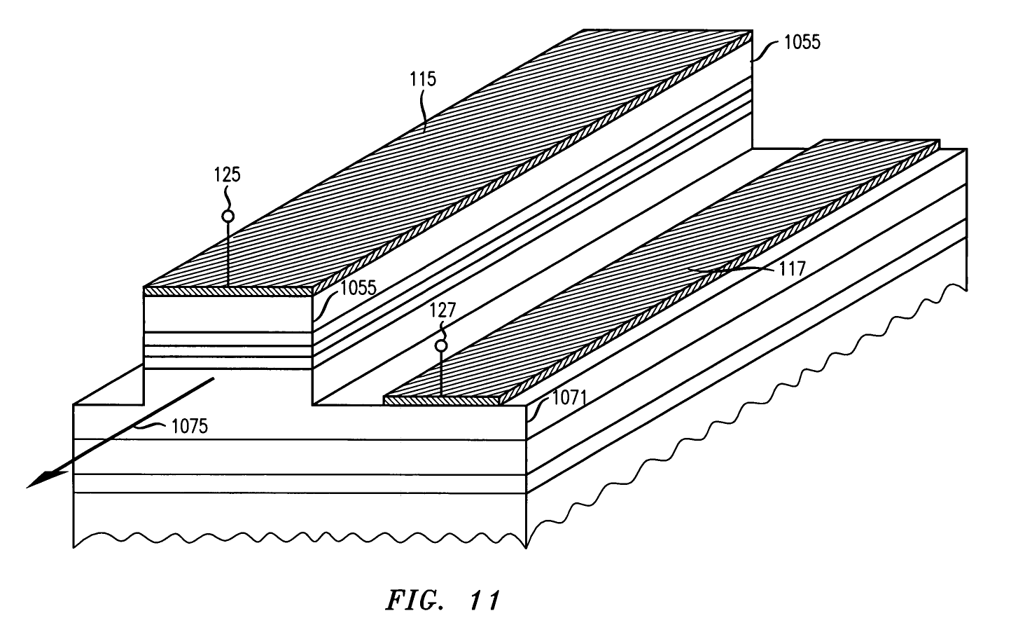

FIG. 10 shows a portion of the cross sectional structure of exemplary quantum cascade laser 1000 which employs multiple repetitions of the layers that form the active region 500 (FIG. 5) and the layers that form superlattice region 700 (FIG. 7). More specifically, shown in FIG. 10 are superlattice regions 1031-1 and 1035-2, collectively superlattice regions 1031, and active regions 1035-1 and 1035-2, collectively active regions 1035. Superlattice regions 1031 act as injection regions, supplying electrons to the multiquantum wells formed in active regions 1035. Active regions 1035 operate to emit light. The number of alternating active regions and superlattice regions employed is at the discretion of the implementer. Furthermore, superlattice region 1031-1 need not be employed, depending on the application. It serves to provide an efficient path for electrons to pass from electrode 1017 to active region 1035-1.

Preferably at the end of the alternating active and superlattice regions of exemplary quantum cascade laser 1000 that is opposite to substrate 1001 is alloyed superlattice region 1035. CaF₂/CdF₂ superlattice region 1035 has a structure similar to that of superlattice region 700 (FIG. 7) but in which the layers of silicon are replaced with CdF₂. The thickness of the various layers of CaF₂/CdF₂ superlattice region 1035 (FIG. 10) is determined by the energy levels that are needed to form a miniband when an operating voltage is applied, as described hereinabove in regards to superlattice region 700 (FIG. 7). CaF₂/CdF₂ superlattice region 1035 (FIG. 10) serves as a conductor but one that confines the light in quantum cascade laser 1000 by virtue of having a lower effective index of refraction than the effective index of refraction presented by its adjacent one of active regions 1035. This confining is the same function performed by SiO₂ layer 102 described hereinabove.

Exemplary quantum cascade laser 1000 also includes a) silicon (Si) substrate 101, b) silicon dioxide layer SiO₂ 102, c) Si layer 103, d) conductive Si (n⁺ Si) layer 105, e) metal layers 115 and 117, and j) conductors 125 and 127.

Molecular beam epitaxy may be employed to deposit the various layers of Si and CaF₂, and CdF₂. For depositing silicon, an e-beam source, e.g., an electron beam evaporator, may be employed as the source of the Si atoms. For CaF₂, CdF₂, and dopants a thermal evaporator, e.g., an effusion cell, may be employed as the source of the molecules.

FIG. 11 shows a portion of a three dimensional view of exemplary quantum cascade laser 1000. Shown in are metal layers 115 and 117 and conductors 125 and 127 as well as faces 1055 and 1071. Faces 1055 are partly reflective to form between them an optical cavity in which lasing takes place. Faces 1055 may be made reflective by cleaving them, or coating them with a reflective substance, or a combination of both. Each of faces 1055 may be made reflective in a manner, and to a degree, that is independent of the other one of faces 1055. Face 1071 is the underlying layers of exemplary quantum cascade laser 1000 such as silicon (Si) substrate 101 silicon dioxide layer SiO₂, Si layer 103, and conductive Si (n⁺ Si) layer. Laser light 1075 is shown being emitted from one of faces 1055.

Those of ordinary skill in the art will readily recognize that semiconductor light sources arranged in accordance with the principles of the invention need not simply be straight but may be shaped into various shapes, e.g., to form a ring resonator laser or a waveguide optical amplifier.

What is claimed is:

1. A semiconductor structure comprising silicon (Si) and calcium fluoride (CaF₂) operable as a light source.

2. The invention as defined in claim 1 wherein said semiconductor structure further includes a least two electrodes.

3. The invention as defined in claim 1 wherein at least one of said silicon and said calcium fluoride are doped.

4. The invention as defined in claim 3 wherein at least some of said silicon is doped with a dopant to be n-type silicon.

5. The invention as defined in claim 4 wherein said dopant is antimony.

6. The invention as defined in claim 3 wherein said calcium fluoride is doped with a dopant to be n-type calcium fluoride.

7. The invention as defined in claim 6 wherein calcium fluoride is alloyed with cadmium flouride.

8. The invention as defined in claim 6 wherein said dopant is gallium.

9. The invention as defined in claim 6 wherein said dopant is one of the set consisting of trivalent metal ions.

10. The invention as defined in claim 1 wherein said semiconductor structure is arranged to have a shape that is not straight.

11. The invention as defined in claim 1 wherein said semiconductor structure is one of the types consisting of: a quantum cascade laser, a ring resonator laser, and a waveguide optical amplifier.

12. The invention as defined in claim 1 wherein said semiconductor structure is adapted to be electrically pumped.

13. The invention as defined in claim 1 wherein said semiconductor structure operates using intersubband transitions.

14. The invention as defined in claim 22 wherein said intersubband transitions take place in the conduction band.

15. The invention as defined in claim 22 wherein said intersubband transitions have a gap of about 0.8 electronvolt.

16. The invention as defined in claim 22 wherein said intersubband transitions have a gap of about 0.95 electronvolt.

17. The invention as defined in claim 1 wherein said Si provides a quantum well and said CaF₂ provides a barrier.

18. The invention as defined in claim 22 wherein said Si is formed into at least one layer that has a thickness in a range from 5 angstroms to 100 angstroms.

19. The invention as defined in claim 22 wherein said CaF₂ is formed into at least one layer has a thickness in a range from 5 angstroms to 50 angstroms.

20. The invention as defined in claim 1 wherein said CaF₂ is formed into at least one layer in which said CaF₂ is alloyed with cadmium fluoride.

21. The invention as defined in claim 20 further including at least one layer of said CaF₂ that is not alloyed with cadmium fluoride and wherein said layer of said alloy of CaF₂ and cadmium fluoride is more readily doped to be conductive than said layer CaF₂ that is not alloyed with cadmium fluoride.

22. The invention as defined in claim 1 wherein said silicon is alloyed with germanium.

23. The invention as defined in claim 22 wherein said alloy of silicon and germanium achieves a near perfect lattice match to said CaF₂.

24. The invention as defined in claim 1 wherein said semiconductor structure provides light in the near infrared spectral range.

25. The invention as defined in claim 1 wherein said semiconductor structure provides light at a wavelength of about 1.5 μm.

26. The invention as defined in claim 1 wherein said semiconductor structure provides light at a wavelength of about 1.3 μm.

27. The invention as defined in claim 1 wherein said semiconductor structure is a laser.

28. The invention as defined in claim 1 wherein at least one surface of said semiconductor structure is at least partially reflective of said light.

29. The invention as defined in claim 1 wherein said semiconductor structure further comprises at least one face coated with a material at least partially reflective of said light.

30. The invention as defined in claim 1 wherein at least one surface of said semiconductor structure is cleaved whereby a natural partial mirror is formed.

31. The invention as defined in claim 1 wherein said silicon and said calcium fluoride are arranged into a multilayer structure.

32. The invention as defined in claim 1 further comprising a superlattice region formed by alternating layers of calcium fluoride and cadmium floride.

33. The invention as defined in claim 1 wherein said silicon and said calcium fluoride are arranged as alternating layers.

34. The invention as defined in claim 33 wherein said alternating layers of said silicon and said calcium fluoride form at least one active region.

35. The invention as defined in claim 33 wherein said alternating layers of said silicon and said calcium fluoride form at least one superlattice region.

36. The invention as defined in claim 33 further comprising a base upon which said alternating layers of said silicon and said calcium fluoride are formed.

37. The invention as defined in claim 36 wherein said base further comprises a substrate of silicon, a layer of silicon dioxide on said substrate of silicon, a layer of silicon on said layer of silicon dioxide, a layer of silicon that is doped to be conductive on said layer of silicon.

38. The invention as defined in claim 37 wherein further comprising a metal layer upon at least a part of said conductive layer of silicon.

39. A method for generating light, comprising the step of injecting one or more electrons into a quantum well structure having a quantum well and a barrier in which a layer comprising substantially silicon forms the quantum well and a layer comprising primarily calcium fluoride provides the barrier.

40. A light source, comprising:
a base;
a silicon electrode upon said base;
a first layer of calcium fluoride upon said silicon electrode;
a first layer of silicon upon said first layer of calcium fluoride; and
a second layer of calcium fluoride upon said first layer of silicon.

41. The invention as defined in claim 40 wherein said base further comprises a silicon substrate.

42. The invention as defined in claim 40 wherein said base further comprises a silicon substrate, a layer of silicon dioxide upon said silicon substrate, a layer of silicon upon said layer of silicon dioxide.

43. The invention as defined in claim 40 further comprising an electrode comprised primarily of calcium fluoride upon said second layer of calcium fluoride.

44. The invention as defined in claim 40 further comprising a plurality of conductors for supplying electricity to said light source, at least one of conductors being connected to said silicon electrode.

45. The invention as defined in claim 40 wherein said light source is arranged to operate as a quantum cascade laser that further comprises:
a second layer of silicon upon said second layer of calcium fluoride; and
a third layer of calcium fluoride upon said second layer silicon.

46. The invention as defined in claim 45 further comprising an electrode comprised primarily of calcium fluoride upon said third layer of calcium fluoride.

47. The invention as defined in claim 45 wherein said light source further comprises two reflective surfaces.

48. The invention as defined in claim 47 wherein one of said reflective surfaces is formed by a coating of reflective material.

49. The invention as defined in claim 47 wherein one of said reflective surfaces is formed by cleaving said layers of silicon and calcium fluoride that are not electrodes.
